(19) United States
(12) Patent Application Publication
(10) Pub. No.: US 2009/0245120 A1
(43) Pub. Date: Oct. 1, 2009

(54) Ethernet Physical Layer Transceiver with Auto-Ranging Function

(75) Inventor: Michael Jones, Newport (GB)

Correspondence Address: PATENT LAW GROUP LLP, 2635 NORTH FIRST STREET, SUITE 223, SAN JOSE, CA, 95134, US

(73) Assignee: MICREL, INC.,, San Jose, CA (US)

(21) Appl. No.: 12/060,499

(22) Filed: Apr. 1, 2008

(51) Int. Cl. G01R 31/08

(52) U.S. Cl. 370/252

(57) ABSTRACT

A method in an Ethernet physical transceiver device for selecting a transmission speed includes resetting a first register and a count value, establishing a link with a remote network device at a first transmission speed, incrementing the first register to a first value, monitoring the link by counting the number of detected false carrier events in the incoming transmission as the count value, and at the expiration of a first time period, comparing the count value of false carrier events to a predetermined threshold. The method continues with reducing the first transmission speed when the count value exceeds the predetermined threshold, maintaining the first transmission speed when the count value is less than the predetermined threshold, and when the first register has a first value, incrementing the first register to a second value and repeating the steps of monitoring the link to reducing the first transmission speed.

### FIELD OF THE INVENTION

The invention relates to data communication devices and, in particular, to an Ethernet communication device providing auto-ranging function to select a high or low bandwidth transmission.

### DESCRIPTION OF THE RELATED ART

Data communication networks, such as local area networks (LANs), are used in interconnecting network devices to facilitate data communication between two or more network devices. Ethernet, described by IEEE standard 802.3, is one of the most commonly used local area networking scheme. Ethernet standard under IEEE 802.3 defines a number of wiring and signaling standards for the physical layer, means of network access at the Media Access Control (MAC)/Data Link Layer, and a common addressing format. Ethernet incorporates a variety of cabling schemes. In general, in a 10Base-T Ethernet or 100Base-TX Ethernet, Category 5 (Cat 5) wiring is used. A Cat 5 cable is a unshielded twisted pair cable containing four twisted wire pairs. Higher grade cables, such as CAT 5e or Cat 6, are also used.

The physical layer of an Ethernet data communication network is the most basic network layer, providing only the means of transmitting raw bits over a physical data link connecting network nodes. The bit stream may be grouped into code words or symbols, and converted to a physical signal, which is transmitted over a physical transmission medium. The physical layer of an Ethernet communication system provides an electrical, mechanical, and procedural interface to the transmission medium. The shapes of the electrical connectors, which frequencies to broadcast on, what modulation scheme to use and similar low-level parameters are specified at the physical layer of the Ethernet communication system. In general, the Ethernet physical layer is realized in the form of a physical layer transceiver, denoted “PHY,” for implementing the interfaces to transmit data over and receive data from the transmission medium. In the following description, the term “Ethernet PHY” is used to refer to the physical layer transceiver in an Ethernet data network.

The 10Base-T Ethernet is the original Ethernet and transmits at a rate of 10 Mbit per second. The 100Base-TX Ethernet is referred to as the Fast Ethernet and carries traffic at the nominal rate of 100 Mbit per second. Both of these Ethernet standards can transmit at half-duplex or full duplex. Under IEEE standard 802.3, each network segment in a 100Base-TX Ethernet can have a maximum distance of 100 meters (330 ft) only.

The requirements for Fast Ethernet impose constraints for implementing Fast Ethernet in a network configured for the 100Base-TX Ethernet. For example, the cable length of the network may have to be checked to ensure that each network segment is less than 100 meters. IEEE 802.3 standard only supports network segments of less than 100 meters. A network operating with cable length greater than 100 meters is considered outside of the 802.3 standard. Alternately, the user can perform on-site testing to determine if the Fast Ethernet speed is achievable and then manually configure both side of a link to operate at the Fast Ethernet speed. However, even when the network has been manually tested to be capable of supporting 100Base-TX communication, changes in the environment, such as temperature, and changes in the quality of the cable can affect the ability of the network to maintain communication at the 100Base-TX level. Furthermore, in some situations, it may be necessary or desirable to use cable length of 100 meters or greater for a network segment while preserving the 100Base-TX communication speed.

### SUMMARY OF THE INVENTION

According to one embodiment of the present invention, a method in an Ethernet physical transceiver device for selecting a transmission speed includes resetting a first register to a reset value and resetting a count value to zero, establishing a link with a remote network device at a first transmission speed, incrementing the first register to a first value, monitoring the link by counting the number of detected false carrier events in the incoming transmission as the count value, and at the expiration of a first time period, comparing the count value of false carrier events to a predetermined threshold. The method continues with reducing the first transmission speed when the count value exceeds the predetermined threshold, maintaining the first transmission speed when the count value is less than the predetermined threshold, and when the first register has a first value, incrementing the first register to a second value and repeating the steps of monitoring the link to reducing the first transmission speed.

The present invention is better understood upon consideration of the detailed description below and the accompanying drawings.

### BRIEF DESCRIPTION OF THE DRAWINGS

FIG. 1 is a schematic diagram of two connected network devices forming an Ethernet network according to one embodiment of the present invention.

FIG. 2 is a schematic diagram of a network device incorporating the auto-ranging circuit according to one embodiment of the present invention.

FIG. 3 is a schematic diagram of a network device incorporating the auto-ranging circuit according to an alternate embodiment of the present invention.

FIG. 4 is a schematic diagram of a network device incorporating the auto-ranging circuit according to a second alternate embodiment of the present invention.

FIG. 5 is a flow chart illustrating the auto-ranging operation according to one embodiment of the present invention.

FIG. 6 is a flow chart illustrating the auto-ranging operation according to an alternate embodiment of the present invention.

### DETAILED DESCRIPTION OF THE PREFERRED EMBODIMENTS

In accordance with the principles of the present invention, an auto-ranging circuit and method is implemented in an Ethernet physical layer transceiver (PHY) for monitoring false carrier events in the received communication and determining the best achievable transmission speed for the Ethernet PHY so that the Ethernet PHY device can be configured to operate at the highest speed regardless of the cable length. More specifically, the auto-ranging circuit and method is applied to allow a network to be implemented with cable lengths that may exceed the specified standard. The auto-ranging circuit and method of the present invention can be used even when the Ethernet PHY does not support auto-negotiation or when auto-negotiation is disabled as long as both link partners implements auto-ranging function in accordance with the present invention. Alternately, an Ethernet PHY device incorporating the auto-ranging circuit of the present invention can operate with a link partner that does not support auto-ranging as long as the link partner supports auto-negotiation.

The auto-ranging circuit and method of the present invention realizes particular advantages when applied in a data network. First, the auto-ranging circuit of the present invention enables longer cable length to be used without requiring on-site testing to determine which speed is achievable. In conventional systems, on-site testing would have to be performed to determine the best transmission speed and then the link partners are manually forced to the achievable speed. On the other hand, the auto-ranging circuit and method of the present invention determines the best achievable speed for the network device so that an Ethernet PHY device incorporating the auto-ranging circuit of the present invention can take advantage of transmission performance that exceeds the IEEE 802.3 standard of maximum link distance.

Second, the auto-ranging circuit of the present invention is compatible with network devices that do not support auto-negotiation and network devices having their auto-negotiation disabled, i.e. network devices operating in force mode. Conventional techniques for establishing a common transmission speed between link partners rely solely on auto-negotiation to establish speed. When auto-negotiation is used, the best achievable speed for each network device is preprogrammed into the network device where the best achievable speed is selected based purely on the capability of the integrated circuit and not the physical media (the cable). Through auto-negotiation, the two link partners establish a common transmission speed that is the fastest that both can handle. The auto-ranging circuit of the present invention introduces the ability to analyze the physical media to decide upon the speed configuration. While the auto-ranging circuit of the present invention can be used with auto-negotiation, the auto-ranging circuit can also be used when the network devices are operating in the force mode without auto-negotiation, as long as both link partners implements the auto-ranging function in accordance with the present invention.

In one embodiment, the auto-ranging circuit of the present invention is fully integrated into an Ethernet PHY device. Therefore, the auto-ranging operation can be carried out without the need for external microprocessor control. Alternately, the auto-ranging circuit of the present invention is implemented externally in an integrated circuit separate from the Ethernet PHY device and can be coupled for use with any fast Ethernet PHY transceiver.

In the present description, an Ethernet physical layer transceiver (PHY) refers to a device for realizing the Ethernet physical layer implementing the interfaces to transmit over and receive data from the transmission medium. In the following description, the term “Ethernet PHY” is used to refer to the physical layer transceiver in an Ethernet data network. The Ethernet PHY can be implemented as a stand-alone transceiver device, or it can be incorporated in an Ethernet switch at each Ethernet port.

Moreover, in the following description, auto-negotiation refers to the Ethernet procedure by which two connected devices choose common transmission parameters, such as speed of the link and the duplex mode (half or full duplex). During auto-negotiation, devices connected at two sides of a new link (“the link partners”) first share their capabilities as for these parameters and then choose the fastest transmission mode they both support. In the Open Systems Interconnection (OSI) model, auto-negotiation resides in the physical layer. The operation of auto-negotiation is as follows. Upon insertion of a CAT-5 cable into an RJ45 connector, a 10Base-T Normal Link Pulse (NLP) is sent between the two connecting network devices in order to verify a working connection. If these link pulses are detected by the connected network devices, then the network devices initiate auto-negotiation process whereby the two connected devices decide upon the speed and the communication mode, such as full or half duplex. In operation, when the connected network devices first detect link with each other, each network device transmits a list of possible modes it can operate at. Once that is done, each network device knows both what it is capable of doing and what the other side is capable of doing. With this information, each connected device can independently pick the best common communication mode and set itself to use that mode.

While auto-negotiation is very useful in establishing a common mode of operation between two link partners, network devices that support auto-negotiation may have their auto-negotiation capability disabled. Furthermore, in some legacy network devices, auto-negotiation is not supported.

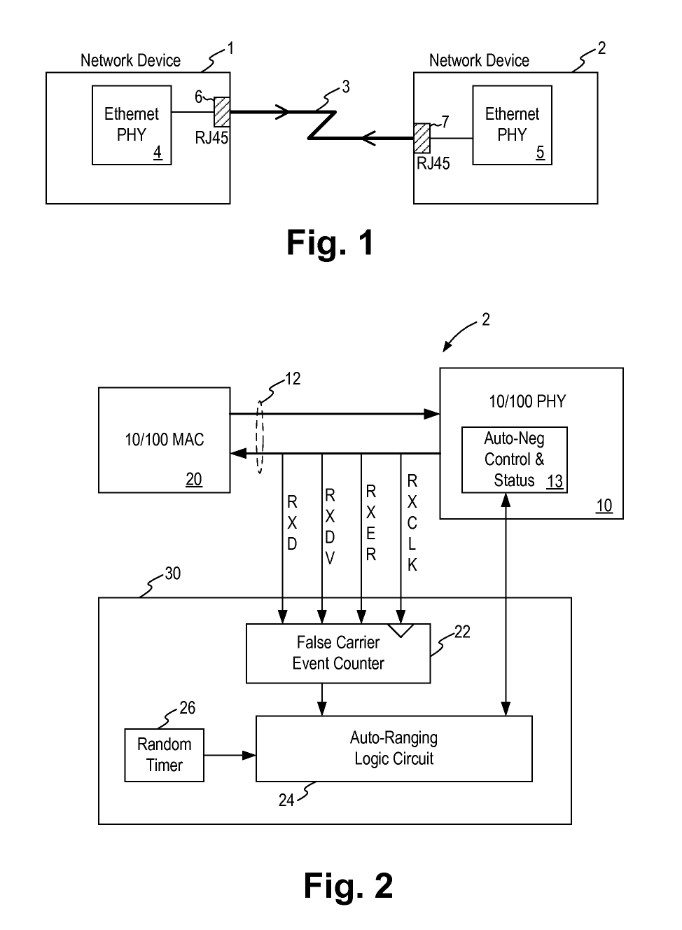

FIG. 1 is a schematic diagram of two connected network work devices forming an Ethernet network according to one embodiment of the present invention. Referring to FIG. 1, a first network device 1 is connected to a second network device 2 through a cable 3. Network devices 1 and 2 are referred to as link partners. More specifically, cable 3 is connected to a RJ45 jack 6 on network device 1 and interfaces with an Ethernet physical layer transceiver (PHY) device 4 for transmitting and receiving data. Cable 3 is also connected to a RJ45 jack 7 on network device 2 and interfaces with an Ethernet physical layer transceiver (PHY) device 5. Network devices 1 and 2 may or may not support auto-negotiation. Furthermore, even when network devices 1 and 2 support auto-negotiation, their auto-negotiation function may be disabled.

More specifically, the auto-ranging circuit and method of the present invention can be applied when only one link partner implements the auto-ranging operation in accordance with the present invention as long as both link partners support auto-negotiation. Alternately, when the link partners are operating in the force mode (i.e., link partners do not support auto-negotiation or both have auto-negotiation disabled), then both link partners must implement auto-ranging to practice the auto-ranging method of the present invention. In some cases, a network device with auto-negotiation enabled may be linked to a network device operating in force mode. In that case, the auto-ranging method of the present invention can be practiced as long as the network device operating in force mode implements the auto-ranging circuit and method of the present invention. The network device with auto-negotiation does not need to implement the auto-ranging circuit and method of the present invention and implementation is optional. The auto-ranging circuit and method of the present invention provides flexibility in implementation and greater compatibility to existing devices.

In the present embodiment, Ethernet PHY device 5 in network device 2 incorporates the auto-ranging circuit of the present invention. Therefore, network device 2 determines the best achievable speed of communication between the two link partners through the auto-ranging operation. Accordingly, cable 3 can have a cable length that exceeds the specified standard and network devices 1 and 2 continue to use the best achievable speed for the given cable length.

FIG. 2 is a schematic diagram of a network device 2 according to one embodiment of the present invention. In the present embodiment, network device 2 is a fast Ethernet device capable of supporting 10Base-T and 100Base-TX communication speeds. Referring to FIG. 2, network device 2 is logically divided into a media access controller (MAC) 20 which deals with the higher level issues of medium availability and a physical layer interface (PHY) device 10. MAC 20 is linked to the PHY device 10 by a synchronous parallel interface 12 referred to as MII (medium independent interface).

In FIG. 2, an auto-ranging circuit 30 is shown as a separate block from the Ethernet PHY device 10. However, this configuration is illustrative only. In other embodiments, auto-ranging circuit 30 is integrated in the Ethernet PHY device 10. The level of integration of auto-ranging circuit 30 is not critical to the practice of the present invention as long as the auto-ranging circuit works cooperatively with the Ethernet PHY device to determine and control the transmission speed of the network device.

To implement auto-ranging operation, network device 2 incorporates auto-ranging circuit 30. Auto-ranging circuit 30 receives four MII signals for monitoring the occurrence of errors in the data communication channel. More specifically, auto-ranging circuit 30 receives the RXCLK (the Receive clock) signal, the RXER (Receive Error Output) signal, the RXDV (Receive Data Valid Output) signal, and the RXD[3:0] (Receive Data Output [3:0]) signal. From the MII signals, auto-ranging circuit 30 monitors the occurrence of errors in the form of false carrier events.

In Ethernet communication, a false carrier event is the detection of a non-idle symbol followed by an idle symbol where the non-idle symbol results due to corruption of the symbol stream where an isolated idle symbol has been corrupted into some other symbol. A false carrier event is signaled by the MII signals as RXER=1, RXDV=0, and RXD[3:0]=1110.

In the present embodiment, it is assumed that Ethernet PHY device 10 supports auto-negotiation. In that case, auto-ranging circuit 30 communicates with Ethernet PHY device 10 by writing to an auto-negotiation control and status register 13 in Ethernet PHY device 10. Auto-negotiation control and status register 13 stores information for causing Ethernet PHY device 10 to either remain at the same transmission speed or downgrade to a lower transmission speed. In the case that the Ethernet PHY device does not support auto-negotiation, auto-ranging circuit 30 communicates with the applicable control and status registers in the Ethernet PHY device for instructing the Ethernet PHY device to use the selected transmission speed.

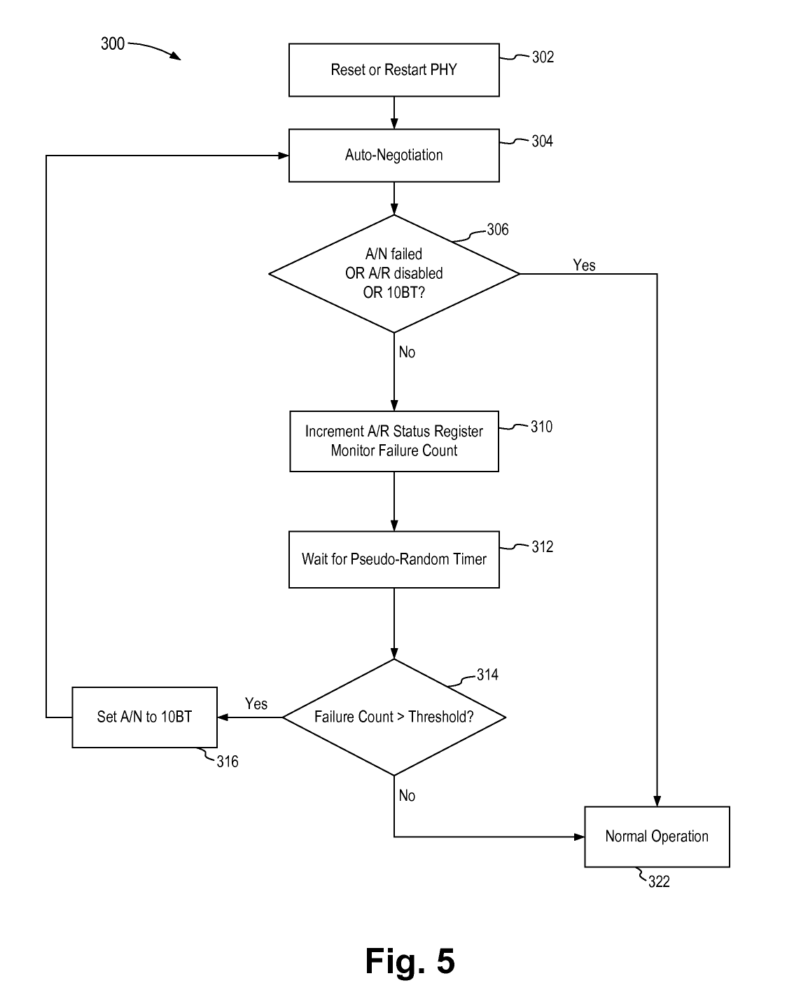

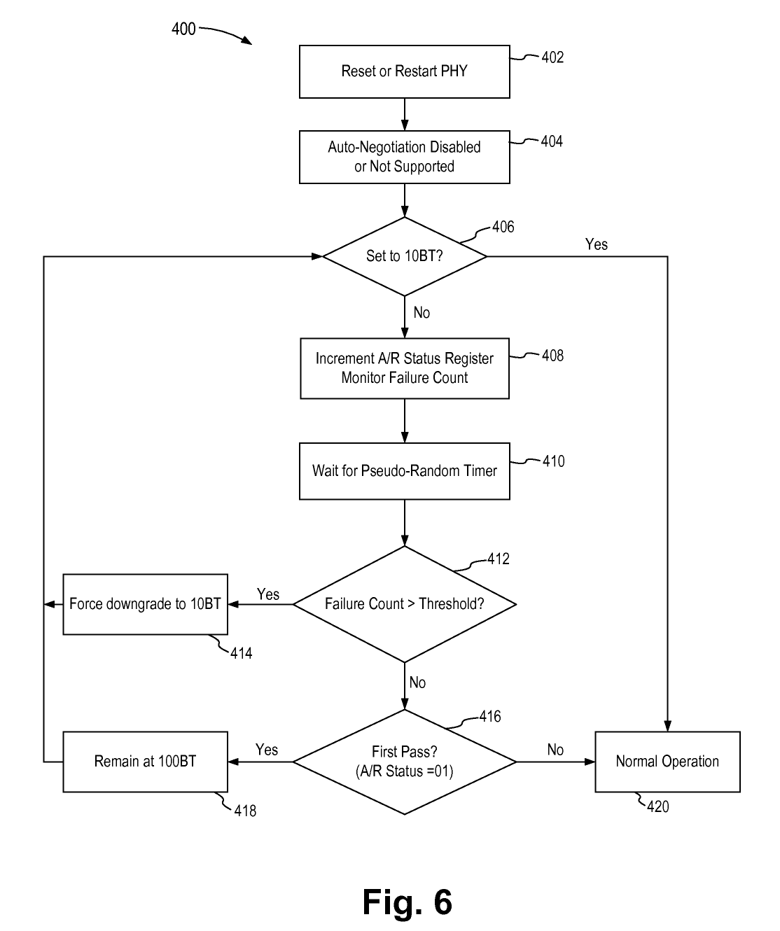

In the present embodiment, auto-ranging circuit 30 includes a false carrier event counter 22, a random timer 26 and an auto-ranging logic circuit 24. False carrier event counter 22 receives the four MII signals and counts the number of false carrier event detected. False carrier event counter 22 generates an error count output signal indicative of the count of false carrier event detected on the MII signals. Random timer 26 generates a random time signal within a given range for auto-ranging logic circuit 24. Auto-ranging logic circuit 24 compares the error count output signal from counter 22 to a predetermined threshold after the expiration of the random time signal. Auto-ranging logic circuit 24 generates control signals for Ethernet PHY device 10 based on the comparison result and writes the control signals in the auto-negotiation control and status register 13. The operation of auto-ranging circuit 30 will be explained in detail below with reference to the flow charts in FIGS. 5 and 6.

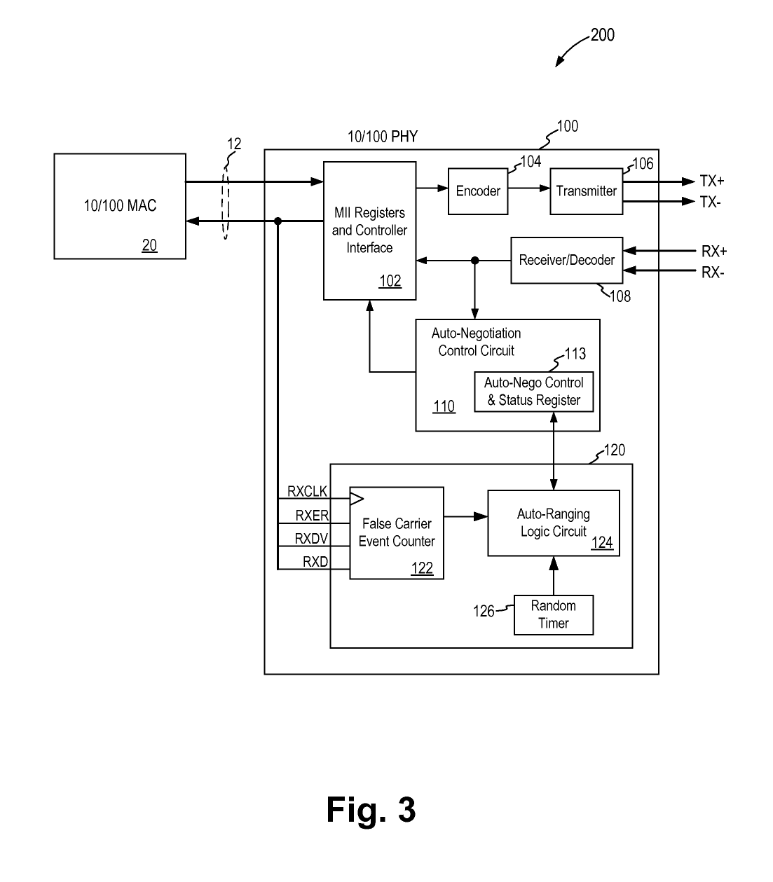

FIG. 3 is a schematic diagram of a network device incorporating the auto-ranging circuit according to an alternate embodiment of the present invention. Referring to FIG. 3, a network device 200 includes a media access controller (MAC) 20 communicating with an Ethernet physical layer transceiver (PHY) 100 over a medium independent interface (MII) 12. Ethernet PHY device 100 includes a MII registers and controller interface 102 for communicating with MAC 20 over MII 12, an encoder 104 for encoding the outgoing data and a transmitter 106 for generating and transmitting the outgoing signals TX+ and TX− onto the communication cable. Ethernet PHY device 100 also includes a receiver and decoder 108 for receiving incoming signals RX+ and RX− and providing the decided incoming signals to the MII registers and controller interface 102.

In the present embodiment, Ethernet PHY device 100 is assumed to support auto-negotiation. Therefore, Ethernet PHY device 100 includes an auto-negotiation control circuit 110 for receiving incoming data signals for determining the appropriate operation mode and generating control signals for MII registers and controller interface 102. Auto-negotiation control circuit 110 includes auto-negotiation control and status register 113 for storing control data for the auto-negotiation operation. In cases where the Ethernet PHY device does not support auto-negotiation, the Ethernet PHY device will include applicable control and status registers for selecting the desired transmission speed and operation modes for the Ethernet PHY device.

Ethernet PHY device 100 further includes an auto-ranging circuit 120 for determining the best achievable transmission speed for the network device 200. In the present embodiment, auto-ranging circuit 120 is integrated in Ethernet PHY device 100. Auto-ranging circuit 120 communicates with the auto-negotiation control and status register 113 in auto-negotiation control circuit 110 for instructing Ethernet PHY device 100 to select the appropriate transmission speed based on the count of the false carrier event. In the case where the Ethernet PHY device does not support auto-negotiation, auto-ranging circuit 120 communicates with the applicable control and status registers of the Ethernet PHY device for instructing the Ethernet PHY device to use the selected transmission speed.

Auto-ranging circuit 120 is configured in the same manner as auto-ranging circuit 30 of FIG. 2 and includes a false carrier event counter 122, a random timer 126 and an auto-ranging logic circuit 124. The operation of auto-ranging circuit 120 will be described in more detail below with reference to FIGS. 5 and 6.

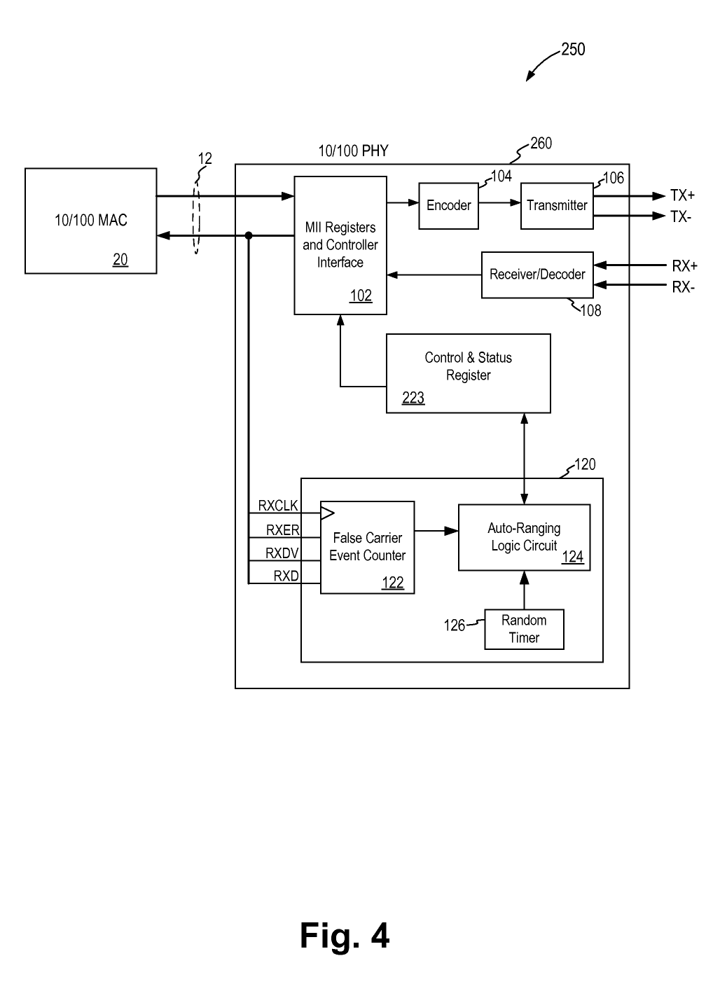

FIG. 4 is a schematic diagram of a network device incorporating the auto-ranging circuit according to a second alternate embodiment of the present invention. Like elements in FIGS. 3 and 4 are given like reference numerals to simplify the discussion. Referring to FIG. 4, a network device 250 is constructed in a similar manner as network device 200 except that Ethernet PHY device 260 in network device 250 does not support auto-negotiation. In that case, auto-ranging circuit 120 communicates with a control and status register 223 which stores control information concerning the transmission speed to be used by Ethernet PHY device 260. Control and status register 223 in turn communicates with the MII registers and controller interface 102. In this manner, the auto-ranging operation in accordance with the present invention is implemented in a network device without auto-negotiation capability.

The operation of the auto-ranging circuit of the present invention will now be described with reference to the flow charts in FIGS. 5 and 6. FIG. 5 is a flow chart illustrating the auto-ranging operation according to one embodiment of the present invention. Auto-ranging method 300 in FIG. 5 is applicable when the Ethernet PHY device coupled to the auto-ranging circuit supports auto-negotiation. FIG. 6 is a flow chart illustrating the auto-ranging operation according to an alternate embodiment of the present invention. Auto-ranging method 400 in FIG. 6 is applicable when the Ethernet PHY device coupled to the auto-ranging circuit does not support auto-negotiation and is operating in the force mode.

Auto-ranging method 300 of FIG. 5 will be described first. Referring to FIG. 5, auto-ranging method 300 is initiated for one of these reset or restart conditions (step 302): when the Ethernet PHY device is reset, when the link partner starts auto-negotiation, when the Ethernet PHY device restarts auto-negotiation on its own; or when the auto-ranging operation is restarted. When method 300 is first initiated, an auto-ranging (A/R) status register is set to a default value of “00”. In one embodiment, the A/R status register and other registers described below are implemented using the register map in the Ethernet PHY device, such as in auto-negotiation control and status register 113 of FIG. 3.

After a reset or restart condition, the Ethernet PHY device performs auto-negotiation (step 304). At this time, the false carrier event counter is reset and a random timer is initiated. At step 306, method 300 determines if auto-negotiation has failed for any reason, or if the auto-ranging operation has been disabled, or if the link partner is capable of transmitting at one speed (10 BT or 100 BT) only and therefore cannot perform auto-ranging. If any one of these conditions exists, then method 300 will instruct the Ethernet PHY device to use the auto-negotiation result and continue in normal mode (step 322). Since auto-ranging has not been performed, the A/R status register is set to a value of “11” indicating that auto-ranging operation has failed.

If none of the above conditions exists, that is, if auto-negotiation has completed, auto-ranging is enabled and the link partner is capable of the fast Ethernet transmission speed (100 BT) as well as the standard Ethernet transmission speed (10 BT), then method 300 proceeds with performing auto-ranging operation at the Ethernet PHY device. The Ethernet PHY device establishes a link with the remote network device using the result of the auto-negotiation. Then, the A/R status register is incremented from the default value and now has a value of “01” and the count of false carrier events is monitored (step 310). Then, method 300 waits for the expiration of a pseudo-random time period generated by the random timer (step 312).

In one embodiment, the pseudo-random time period is set to be 150 ms±10%. In other embodiments, other pseudo-random time period can be used. A given time period is used here to let the false carrier event counter run for a certain time period to collect sufficient error count for comparison with an error threshold. The use of a 150 ms time duration is illustrative only and other time duration can also be used, such as 100 ms. The exact time duration for the pseudo-random time period is not critical to the practice of the present invention. Moreover, a pseudo-random time period is used in auto-ranging method 300 to avoid the situation where both link partners perform auto-ranging operation at the same time. The use of a pseudo-random time period within ±10% of the selected time duration is illustrative only. In other embodiments, the pseudo-random time period can be established using an arbitrary variation from the selected time duration, such as ±5% or ±15%.

At the expiration of the pseudo-random time period, the count of the false carrier event is compared against a predetermined threshold (step 314). The threshold is selected to represent the desired permissible cable performance. That is, in some cases, some errors are tolerated in lure of operating at a high transmission rate. The threshold can thus be selected to give the desired cable performance while maximizing transmission speed.

If the failure count exceeds the threshold, then method 300 will write to the auto-negotiation control and status register to instruct the Ethernet PHY device to start auto-negotiation to downgrade transmission speed to 10 BT (step 316). Method 300 then returns to step 304 when auto-negotiation is carried out. If the failure count is less then the threshold value, then method 300 determines that the link is good and 100 BT is acceptable. Auto-ranging operation is completed and the Ethernet PHY device proceeds to normal operation (step 322).

As described above, auto-ranging method 300 uses auto-negotiation to establish the best achievable transmission speed with the link partner. In this manner, regardless of the length of the cable between the two link partners, the Ethernet PHY device uses the auto-ranging method of the present invention to determine the fastest transmission speed that gives an acceptable level of errors. Auto-ranging method 300 operates based on the assumption that both link partners support auto-negotiation. In that case, only one of the link partners need to support auto-ranging to implement the auto-ranging method 300 of the present invention. It is optional for the other link partner to implement the auto-ranging method 300.

In the case when the link partners are operating in the force mode, that is, neither link partner supports auto-negotiation or when auto-negotiation is disabled at both link partner, auto-ranging method 400 of FIG. 6 is used. Auto-ranging method 400 requires that both link partners implement the auto-ranging circuit and method of the present invention. Referring to FIG. 6, auto-ranging method 400 is initiated for one of these reset or restart conditions (step 402): when the Ethernet PHY device is reset or restarted, or when the auto-ranging operation is restarted. When method 400 is first initiated, an auto-ranging (A/R) status register is set to a default value of “00”.

After the reset or restart condition, the Ethernet PHY device determines that either auto-negotiation has been disabled or is not supported (step 404). At this time, the false carrier event counter is reset and the random timer is initiated. If the device has been configured for 10 BT transmission speed or if auto-ranging is disabled (step 406), then the auto-ranging operation cannot proceed. The auto-ranging method fails and the Ethernet PHY device proceeds to normal operation using the transmission speed selected by the force mode operation (step 420). The A/R status register is set to “11” to signal an auto-ranging failure. If these conditions are not true, then the Ethernet PHY device establishes a link with the remote link partner at a data rate of 100 BT. The A/R status register is incremented from the default value and now has a value of “01” and the count of false carrier events is monitored (step 408). Then, method 400 waits for the expiration of a pseudo-random time period generated by the random timer (step 410). In one embodiment, the pseudo-random time period is 150 ms±10%. As discussed above, the pseudo-random time period can be based on other time duration and other percentage variation about the selected time duration. A pseudo-random time period is applied to avoid both link partners performing auto-ranging operation at the same time. At the expiration of the pseudo-random time period, the count of the false carrier event is compared against a predetermined threshold (step 412).

If the failure count exceeds the threshold, then method 400 will write to the control and status register of the Ethernet PHY device to force the Ethernet PHY device to downgrade transmission speed to 10 BT (step 414). Method 400 then returns to step 406 where the selected transmission is set for Ethernet PHY device and the Ethernet PHY device proceeds to normal operation (step 420).

If the failure count is less then the threshold value, then method 400 determines if the current operation is only the first pass of the auto-ranging operation (step 416). If method 400 is currently on the first pass of the auto-ranging operation, the A/R status register will have a value of “01.” Thus, at step 416, method 400 checks the A/R status register value. If this is the first pass, then method 400 will instruct the Ethernet PHY device to remain at the faster transmission speed of 100 BT (step 418). Method 400 then returns to step 406 where the selected transmission is set for Ethernet PHY device. If this is not the first pass (step 416), then method 400 completes auto-ranging operation and proceeds to normal operation (step 420).

In accordance with the present invention, when the failure count does not exceed the threshold, the auto-ranging operation is run through a second time to ensure that there is no mismatch in selected speeds between the two link partners. A mismatch may occur when the error rate is close to the threshold (assuming both link partners are programmed with the same threshold) or if the two link partners have different programmed failure thresholds. In these cases, there is a possibility where one link partner has a failure count that is less than the threshold and thus remains at 100 BT (step 418) and the other link partner has a failure count that is greater than the threshold and drops to 10 BT (step 414). This result would cause a mismatch with the selected speeds on the communication link and cause the link to go down.

To overcome the potential mismatch issue when the link partners are operating in the force mode, when the auto-ranging error rate does not exceed the threshold, i.e. when the Ethernet PHY device remains at 100 BT (step 418), auto-ranging method 400 will pass through the algorithm a second time. The second pass is to effectively check the result of the link partner. During the first pass, if the link partner also remained at 100 BT, then during the second pass, the failure count will remain less than the threshold (step 412) and the Ethernet PHY device can stay in 100 BT in normal operation (step 420). However, if the link partner has dropped to 10 BT, the mismatch in the speed will result in false carrier events and ensure that the failure count is greater than the threshold (step 412). Hence, during the second pass, the Ethernet PHY device will then be forced to drop back to 10 BT (step 414) and then proceed to normal operation (step 420).

The mismatch situation does not occur when auto-negotiation is enabled at both link partners. When auto-negotiation is enabled, the link partner that is dropping to 10 BT will use auto-negotiation to cause the other link partner to also drop to 10 BT so that both link partners are ensured to communicate at the same speed. In the case where one link partner has auto-negotiation enabled but the other link partner is operating in force mode, a mismatch in transmission speed from the link partner dropping to 10 BT will cause errors and bring the link down. When the link is down, the Ethernet PHY device with auto-negotiation enabled will restart the auto-negotiation process which results in a speed of 10 BT due to the link partner being forced to 10 BT. The communication link will then successfully come back up in 10 BT. In this case, at a minimum only the link partner operating in force mode must support and enable auto-ranging.

In another situation, the link partners have established a 100 BT transmission. However, one link partner may start to experience poor transmission quality and downgrade to 10 BT. The other link partner may not downgrade and may remain at the higher speed. In accordance with the present invention, the auto-ranging method is run through twice so that when one link partner downgrades, the other link partner will detect the downgrade on the second pass and will then force itself to downgrade as well. The second pass of the auto-ranging operation can be implemented in method 300 where the link partners implement auto-negotiation and in method 400 where the link partners operation in the force mode.

The auto-ranging circuit and method of the present invention provides many advantages over conventional solutions. First, by using the auto-ranging circuit and method of the present invention, the cable length can deviate from the specified standard and allow longer length cable to be used. This is especially true when higher grade cable is used, such as CAT5e or CAT6, so that cable distance greater than the specified standard can be achieved. Second, the auto-ranging circuit and method of the present invention allows the best achievable transmission speed to be selected regarding of the environment. The circuit and method of the present invention allow a few errors to be tolerated and only downgrade when the errors exceed a threshold.

The above detailed descriptions are provided to illustrate specific embodiments of the present invention and are not intended to be limiting. Numerous modifications and variations within the scope of the present invention are possible. The present invention is defined by the appended claims.

I claim:

1. A method in an Ethernet physical transceiver device for selecting a transmission speed, the method comprising:
resetting a first register to a reset value and resetting a count value to zero;
establishing a link with a remote network device at a first transmission speed;
incrementing the first register to a first value;
monitoring the link by counting the number of detected false carrier events in the incoming transmission as the count value;
at the expiration of a first time period, comparing the count value of false carrier events to a predetermined threshold;
reducing the first transmission speed when the count value exceeds the predetermined threshold;
maintaining the first transmission speed when the count value is less than the predetermined threshold; and
when the first register has a first value, incrementing the first register to a second value and repeating the steps of monitoring the link to reducing the first transmission speed.

2. The method of claim 1, wherein reducing the first transmission speed when the count value exceeds the predetermined threshold comprises reducing the first transmission speed through auto-negotiation when the count value exceeds the predetermined threshold.

3. The method of claim 1, wherein reducing the first transmission speed when the count value exceeds the predetermined threshold comprises reducing the first transmission speed through force mode operation when the count value exceeds the predetermined threshold.

4. The method of claim 1, wherein maintaining the first transmission speed when the count value is less than the predetermined threshold comprises maintaining the first transmission speed through force mode operation when the count value is less than the predetermined threshold.

5. The method of claim 1, wherein the first transmission speed comprises a 100Base-TX transmission speed and reducing the first transmission speed when the count value exceeds the predetermined threshold comprises reducing the first transmission speed to 10Base-T when the count value exceeds the predetermined threshold.

6. The method of claim 1, wherein the first time period comprises a pseudo-random time period.

7. The method of claim 6, wherein the pseudo-random time period comprises a pseudo-random time period is selected from a variation about a fixed time duration.

8. An auto-ranging circuit for an Ethernet physical transceiver device comprising:
a false carrier event counter receiving data signals from the incoming transmissions and counting the number of detected false carrier events, the false carrier event counter generating a count value;
a timer circuit generating a first time period; and
an auto-ranging logic circuit receiving the first count value and after the first time period, comparing the first count value to a predetermined threshold, the auto-ranging logic circuit causing the Ethernet physical transceiver device to reduce its transmission rate when the count value exceeds the predetermined threshold and when the coutn value does not exeed the predetermined threshold, the auto-ranging logic circuit receives the first count value after another first time period and repeats the comparing operation.

9. The auto-ranging circuit of claim 8, wherein the auto-ranging logic circuit instructs the Ethernet physical transceiver device to reduce its transmission rate when the count value exceeds the predetermined threshold by writing to a control and status register in the Ethernet physical transceiver device.

10. The auto-ranging circuit of claim 8, wherein the auto-ranging logic circuit instructs the Ethernet physical transceiver device to reduce its transmission rate when the count value exceeds the predetermined threshold through auto-negotiation.

11. The auto-ranging circuit of claim 10, wherein the auto-ranging logic circuit instructs the Ethernet physical transceiver device to reduce its transmission rate when the count value exceeds the predetermined threshold by writing to an auto-negotiation control and status register.

12. The auto-ranging circuit of claim 8, wherein the auto-ranging logic circuit instructs the Ethernet physical transceiver device to reduce its transmission rate when the count value exceeds the predetermined threshold through force mode operation.

13. The auto-ranging circuit of claim 8, wherein the false carrier event counter receives four media independent interface (MII) signals for counting the number of detected false carrier events, the four MII signals comprising the receive clock signal, the receive error output signal, the receive data valid output signal and the receive data signals.

14. The auto-ranging circuit of claim 8, wherein the auto-ranging circuit is integrated in the Ethernet physical transceiver device.

15. The auto-ranging circuit of claim 8, wherein the auto-ranging circuit is formed on an integrated circuit separate from the Ethernet physical transceiver device.
